(19) United States
(12) Patent Application Publication
(10) Pub. No.: US 2026/0364737 A1
(43) Pub. Date: Nov. 19, 2026

(54) POLISHING HEAD FOR POLISHING APPARATUS

(71) Applicant: KCTECH CO., LTD., Gyeonggi-do (KR)

(72) Inventors: Bae Ho LEE, Gyeonggi-do (KR); Seong Hyeon PARK, Gyeonggi-do (KR)

(21) Appl. No.: 19/675,667

(22) Filed: May 13, 2026

(30) Foreign Application Priority Data
May 14, 2025 (KR) 10-2025-0062388

(51) Int. Cl. B24B 37/20; B24B 37/005; H10P 72/00

(52) U.S. Cl. CPC B24B 37/20; B24B 37/005; H10P 72/0428

(57) ABSTRACT

The present disclosure relates to a polishing head for a polishing device, the polishing head pressing a substrate having a non-circular shape during a polishing process, the polishing head including a body part that receives a rotational driving force and is formed to be rotatable, a membrane that is coupled to the body part, forms a pressing chamber between the body part and the membrane, and has a bottom surface that presses the substrate, and an edge ring having a receiving through-portion accommodating the substrate in the non-circular shape and coupled to the body part, wherein the polishing process is performed while an entire surface of the substrate is pressed in close contact with a bottom plate of the membrane having a step formed along the receiving through-portion in a state in which a polygonal substrate is seated on the receiving through-portion.

### CROSS-REFERENCE TO RELATED APPLICATIONS

This application claims the benefit of, priority to, the Korean Patent Application No. 10-2025-0062388 filed on May 14, 2025, which is hereby incorporated by reference as if fully set forth herein.

### FIELD

The present disclosure relates to a polishing head for a polishing apparatus, and more particularly, to a polishing head for a polishing apparatus used for polishing a polygonal substrate while rotating each of the substrate and a turntable by themselves in a state in which the substrate is in close contact with a polishing pad of the turntable.

### BACKGROUND

In general, display devices widely employ glass substrates having excellent strength and transmittance. In recent years, the display devices aim for slimming and high pixels, and thus a glass substrate corresponding thereto should be prepared.

As an example, in an excimer laser annealing (ELA) process which is one of organic light emitting diode (OLED) processes and in which amorphous silicon (a-Si) is irradiated with a laser to be crystallized into polysilicon (poly-Si), protrusions may be generated on a surface as the amorphous silicon is crystallized into the polysilicon, these protrusions may cause a mura effect, and thus the glass substrate should be polished so that the protrusions are removed.

A substrate treating apparatus 9 illustrated in FIG. 1 polishes a surface of a substrate G while a polishing head 30 having a bottom surface covered with a polishing pad having a smaller area than a substrate G rotates and moves (indicated by reference numeral 30d) in a state in which the substrate G is mounted on a stage 10, and at the same time, a gantry 20 on which the polishing head 30 is mounted moves (indicated by reference numeral 20d) along a moving rail 22.

However, the substrate G used in the display device is formed as a large-area rectangular flat plate having a length of one side of 1,000 mm or more, and thus an excessively long time is consumed in a process of polishing the entire surface of the substrate G while the small-sized polishing head moves.

In addition, a portion of the surface of the substrate G is polished with the polishing pad, and thus, a possibility of a deviation between polishing rates on the entire substrate cannot be avoided.

In recent years, a substrate used in the display device has been generally formed with a constant thickness, and thus it is required to polish the substrate to a more precise and flat surface. Further, there is a need to reduce a time consumed for a process of polishing a large-area substrate used in manufacturing a display device or a semiconductor package.

The above-described configuration is provided for comparison with the present disclosure and does not mean a technology widely known before a filing date of the present disclosure.

### SUMMARY

The purpose of the present disclosure is to improve process efficiency by increasing the number of large-area substrates polished per unit time by polishing an entire surface of the substrate at once when polishing the substrate having a quadrangular flat plate shape having a length of one side of 500 mm or more used in a display device.

At the same time, the purpose of the present disclosure is to prevent distortion and jamming of a substrate during a polishing process even when the substrate has a non-circular shape and to uniformly polish a central portion, an edge area, and a vertex area of the substrate.

Above all, the purpose of the present disclosure is to securely prevent distortion of a pressing force applied to a large-area substrate due to local bending or overlapping of a membrane forming a pressing chamber that presses the large-area substrate and thus to perform accurate polishing areas near edges of the large-area substrate at a predetermined polishing amount per unit time.

According to an aspect of the present disclosure, there is a polishing head for a polishing apparatus, which presses a substrate having a non-circular shape during a polishing process, the polishing head including a body part that receives a rotational driving force and formed to be rotatable, a membrane that is coupled to the body part, forms a pressing chamber between the body part and the membrane, and has a bottom surface that presses the substrate, and an edge ring having a receiving through-portion accommodating the substrate in the non-circular shape and coupled to the body part, wherein the polishing process is performed while an entire surface of the substrate is pressed in close contact with a bottom plate of the membrane having a step formed along the receiving through-portion in a state in which the polygonal substrate is seated on the receiving through-portion.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a view illustrating a configuration of a conventional substrate treating apparatus;

FIGS. 2A, 2B and 2C are plan views illustrating a configuration of a substrate treating apparatus according to a first embodiment of the present disclosure and are plan views illustrating a configuration according to a process sequence in which a substrate is supplied and a polishing process is performed;

FIG. 3A is a perspective view illustrating the configuration of FIG. 2B excluding a slurry supply unit and a conditioner;

FIG. 3B is a perspective view illustrating the configuration of FIG. 2C excluding the slurry supply unit and the conditioner;

FIG. 4 is a half cross-sectional view of a polishing head of FIG. 3B;

FIG. 5 is an exploded view of FIG. 4;

FIG. 6 is an enlarged view of portion "A" of FIG. 4;

FIG. 7A is an enlarged view of portion "B" of FIG. 4;

FIG. 7B is an enlarged view illustrating a configuration according to another embodiment of the present disclosure corresponding to portion "B" of FIG. 4;

FIG. 8 is a bottom view of the polishing head of FIG. 4 and is a view illustrating positions of a flap of a membrane and a receiving through-portion;

FIG. 9 is a longitudinal sectional view illustrating a configuration of an edge ring of the polishing head of FIG. 4; and

FIG. 10 is a half cross-sectional view illustrating a configuration of the membrane of the polishing head of FIG. 4.

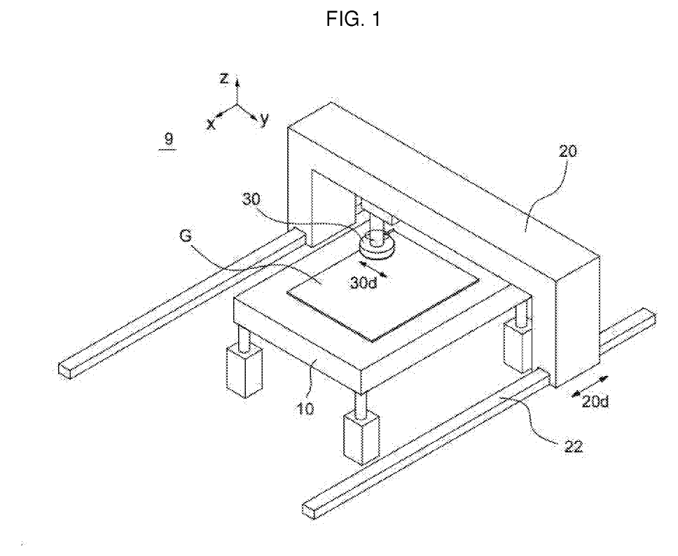

### DETAILED DESCRIPTION

Hereinafter, exemplary embodiments of the present disclosure will be described in detail with reference to the accompanying drawings, but the present disclosure is not limited or restricted by the embodiments. For reference, in this description, the same reference numerals denote substantially the same elements, under this rule, descriptions may be provided by citing contents described in other drawings, and contents that are determined to be obvious to those skilled in the art or are repeated may be omitted.

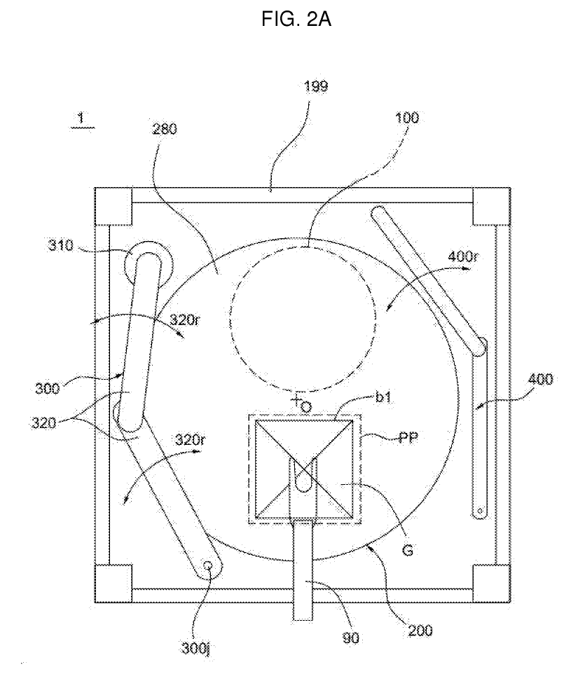

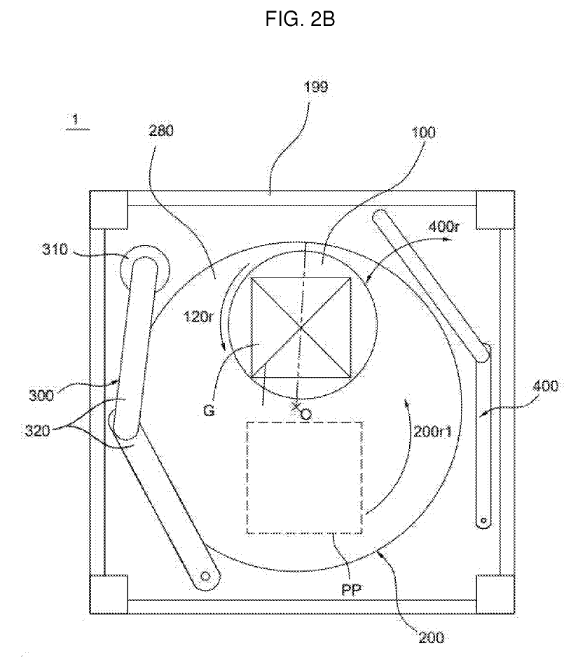

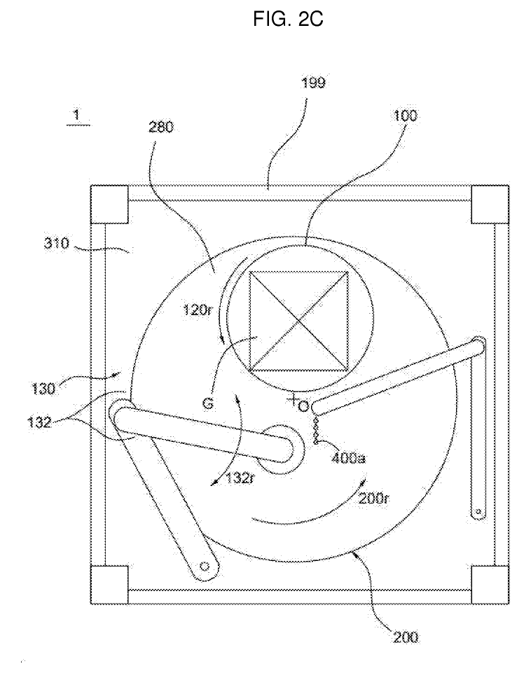

As illustrated in the drawings, a substrate treating apparatus 1 according to the present disclosure includes a turntable 200 having an upper surface formed as a flat surface and rotating by itself during a polishing process, a polishing head 100 that rotates by itself while pressing a substrate G against a flat surface of a polishing pad 280 in a state in which the substrate G is positioned on a lower side, a conditioner 300 that modifies a surface state of the polishing pad 280 during the polishing process for the substrate G, and a slurry supply unit 400 that supplies a slurry between the substrate G and the polishing pad 280. As illustrated in FIGS. 2A to 2C, the substrate treating apparatus 1 is maintained in a sealed state by an inner wall 199 so that an internal liquid is prevented from leaking to the outside during the polishing process.

Here, the substrate G is a large-area substrate having a width and length of approximately 500 mm or more, and a substrate formed of a material such as glass and used to manufacture a display device or a semiconductor package may be applied to the substrate G. In some cases, the substrate G includes a substrate formed of titanium or copper. However, the present disclosure is not limited to a dimension of the substrate G, a substrate having a smaller size than this may be applied, and the substrate G may be formed in various shapes such as a polygonal shape or an elliptical shape in addition to a quadrangular shape.

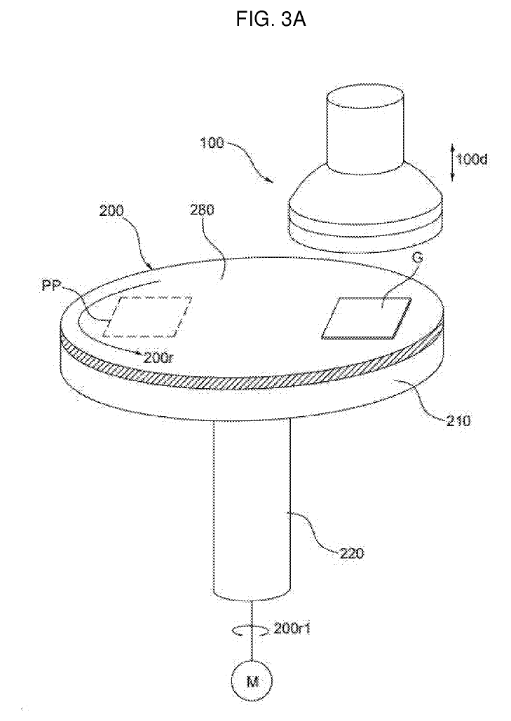

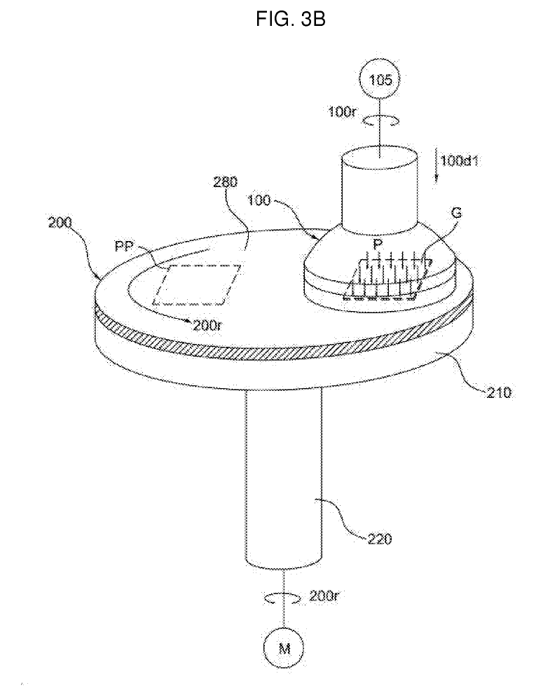

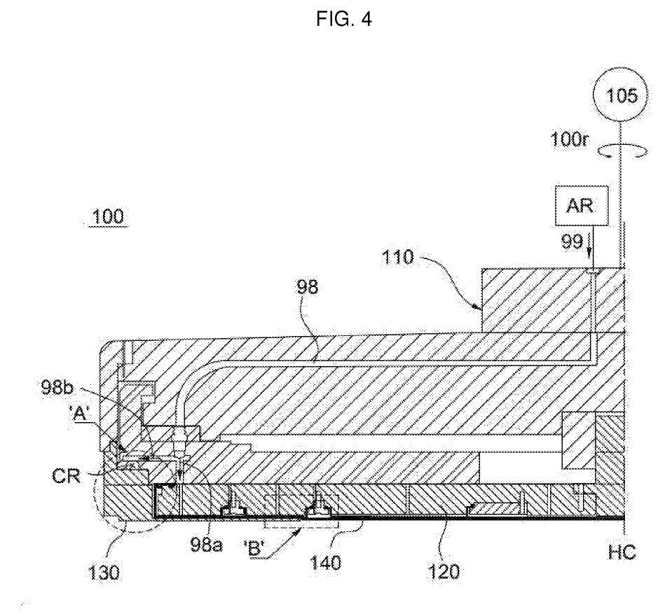

As illustrated in FIG. 3B, the turntable 200 includes a rotary shaft 220 that rotates (indicated by reference numeral 200r) by receiving a rotational driving force from a driving motor M and a circular disk-shaped plate 210 which has a flat surface on the rotary shaft 220 and of which an area is greater than a cross section of the rotary shaft 220.

The rotary shaft 220 may be directly driven by the driving motor M or may be rotated and driven by receiving a rotational driving force through a pinion and a belt that are rotated and driven by the driving motor M.

The upper surface of the turntable 200 is formed as a flat surface, and the flat surface is covered with the polishing pad 280 having a higher hardness than the substrate G and formed as an upper surface of the polishing pad 280.

Further, a cooling plate having a cooling water flow path formed therein is interposed between the polishing pad 280 and the circular plate 210 to decrease a temperature of the polishing pad 280 heated during the polishing process.

The polishing head 100 is installed to be movable in an up-down direction 100d, and at the same time, is formed to perform self-rotation 100r by a head driving unit 105. The polishing head 100 presses the substrate G downward during the polishing process to bring a polishing surface of the substrate G into close contact with the polishing pad 280 by a predetermined pressing force.

A detailed configuration of the polishing pad 280 will be described below.

The conditioner 300 includes arms 320 that rotate about a column 300j positioned outside the turntable 200 and a conditioning disk 310 that moves by a pivoting motion 320r of the arm 320 and modifies the polishing pad 280 while in contact with the polishing pad 280 while performing both the pivoting motion 320r and the self-rotation during the polishing process or an interval between the polishing processes.

The slurry supply unit 400 supplies the slurry to a rotation center O of the polishing pad 280 or a portion adjacent to the substrate G during the polishing process so that the substrate G may be chemically polished.

The substrate G used in the polishing process is a substrate used for manufacturing a display device and a semiconductor packages and a large-area substrate having a length of one side of 500 mm or more is used. Further, a thickness of the substrate G has been used to be 1.1 mm or less for a fourth-generation substrate, but recently, the substrate G having a thickness of 0.5 mm or less is used for eleventh-generation and later substrates. Accordingly, unlike a substrate such as a wafer for manufacturing a semiconductor package, a large-area glass substrate used for manufacturing a display device or a semiconductor package is thin and easily undergoes bending deformation, and thus it is difficult to mount the glass substrate on the polishing head 100.

Thus, as illustrated in FIG. 2A, the substrate G is mounded by a transfer arm 90 at a predetermined position PP with respect to the center O of the turntable 200 in a predetermined posture. For example, one side b1 of the substrate G may be disposed to be parallel to a rotational tangential direction toward the rotation center O of the polishing pad 280, and the substrate G may be positioned such that a center of the substrate G is aligned with a middle position between the rotation center O and a radial end of the polishing pad 280. As needed, a detection sensor is provided to detect a position and posture of the substrate G mounded on the polishing pad 280 to identify whether the substrate G is mounded at the predetermined position PP in the predetermined posture.

Here, the predetermined position PP does not refer to a specific position based on the polishing pad 280 but refers to a coordinate position on the polishing pad 280 spaced a predetermined distance from the polishing head 100.

In this case, the predetermined position PP may be determined as a position rotated by 180 degrees in a circumferential direction based on a position in which the polishing pad 280 is disposed, and thus interference between the movement of the polishing pad 280 in the up-down direction 100d and the transfer arm 90 may be avoided. This is because, when a length of the one side b1 of the substrate G is very large, e.g., 3,300 mm or more, a dimension of the polishing head 100 is also very large, there is a limitation in precisely transferring the polishing head 100 in a horizontal direction, equipment becomes excessive, and thus it is required to accurately position the substrate G with respect to the polishing head 100 even when the polishing head 100 moves only in an up-down direction.

Then, as illustrated in FIGS. 2B and 3A, the turntable 200 is rotated (indicated by reference numeral 200r1) by a predetermined angle (e.g., 180 degrees) to move the substrate G to an alignment position below the polishing head 100.

Next, as illustrated in FIG. 3B, the polishing head 100 moves (indicated by reference numeral 100d1) downward. The substrate G is positioned to be aligned below the polishing head 100, and thus, even when movement of the polishing head 100 in the horizontal direction is restricted and only movement thereof in the up-down direction 100d is allowed, the quadrangular substrate G is accurately accommodated in a quadrangular central through portion of an edge ring 130 when the polishing head 100 moves downward and a bottom surface of an edge ring 130 comes into contact with the polishing pad 280.

By this process, in performing a process of pressing the large-area substrate G against the polishing head 100 in a state in which the substrate G is mounded on the turntable 200, the polishing process may be performed while a possibility of damage to the substrate G is minimized and the substrate G is efficiently fixed to the polishing head 100 and rotated.

A case in which the substrate G has a quadrangular shape is exemplified in the embodiment illustrated in the drawings, but the present disclosure is not limited thereto, and various shapes such as a polygonal shape such as a triangular shape and a pentagonal shape and an elliptic shape may be applied.

In order for a non-circular large-area glass substrate G used in manufacturing a display device or a semiconductor package to be pressed against the polishing pad 280 with a predetermined force P by the polishing head 100 while the substrate G is suppressed from being separated outward from the polishing head 100 during the polishing process as illustrated in FIG. 3B, a structure capable of accommodating the non-circular substrate G without damage is required.

That is, a polishing apparatus that performs polishing while pressing an entire surface of the substrate against the polishing pad and rotating the polishing pad and the substrate in a state in which the substrate is positioned below the polishing head has conventionally been applied only to a substrate having a circular disk shape. However, when the substrate used in the display device is formed in a circular shape, a problem in efficiency occurs because the substrate other than a quadrangle should be cut and removed.

Thus, the polishing head 100 according to the present disclosure is configured to improve polishing quality of the substrate while damage to the substrate is prevented during the polishing process even when the substrate has a polygonal shape rather than a circular shape.

To this end, the polishing head 100 includes a body part that includes a head body 110 and a base member 120, receives a rotational driving force, and is rotatably formed, a membrane 140 that is coupled to the body part, forms a pressing chamber C between a bottom surface of the base member 120 and the membrane 140, and having a bottom plate 141 for pressing the substrate G, and an edge ring 130 surrounding the bottom plate 141 of the membrane 140, connected to the body part, and having a receiving through-portion 130x that accommodates the substrate G.

Here, the head body 110 rotates (indicated by reference numeral 100r) by receiving a rotational driving force from the rotation driving unit 105, and a pneumatic passage 98 for supplying a pneumatic pressure to the pressing chambers C1, C2, ..., Ce, and CR is formed. Although the pneumatic passage 98 is schematically illustrated in the drawings, a pneumatic pressure 99 is supplied to the head body 110 through a pressure adjusting unit AR such as a rotary union, and thus that the independent pneumatic pressure 99 is supplied to the pressing chambers C1, C2, ..., Ce, and CR.

The base member 120 is coupled to the head body 110 or is installed at least in a state of interfering in a self-rotation direction. Accordingly, when a rotational driving force is transmitted from the driving unit 105 to the head body 110, the base member 120 also performs self-rotation 100r integrally with the head body 110.

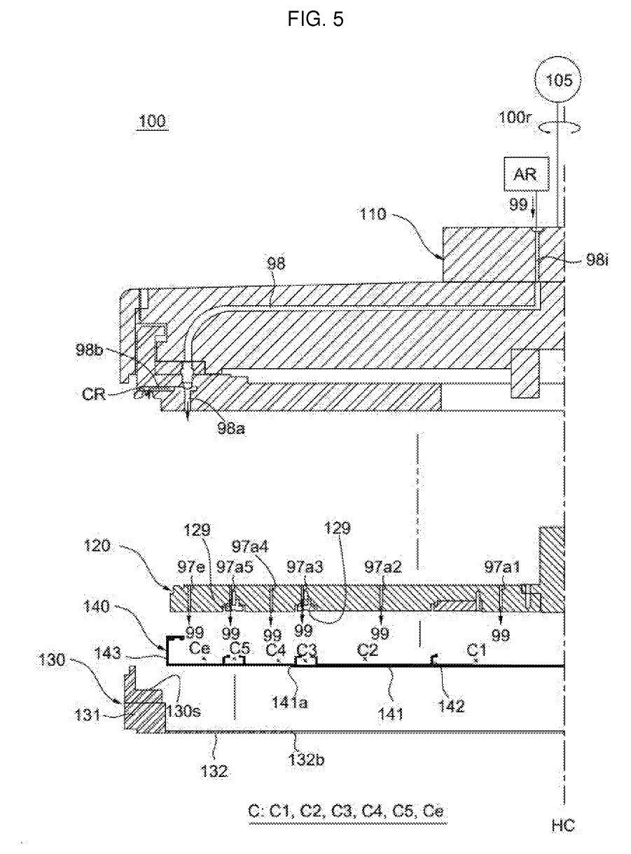

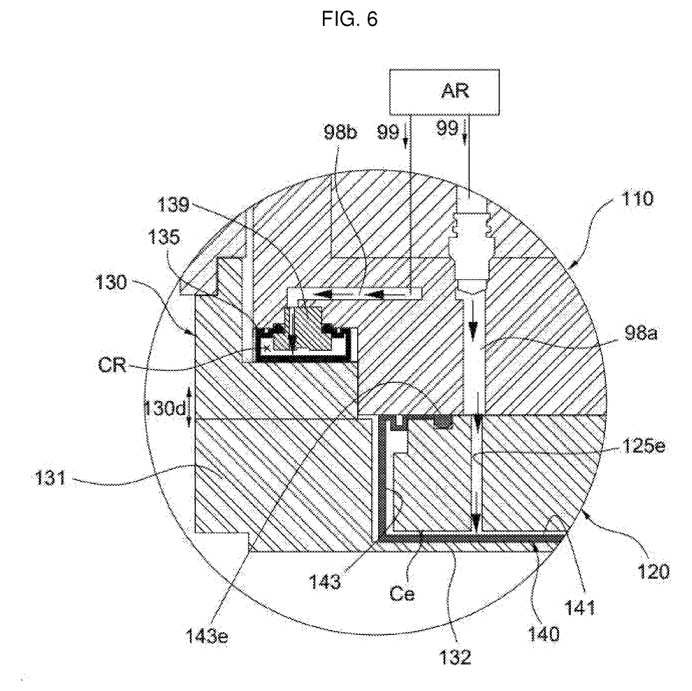

As illustrated in FIG. 5, the membrane 140 is coupled to the base member 120 with a predetermined distance between the bottom surface of the base member 120 and the bottom plate 141 of the membrane 140. Pneumatic passages 97a1, 97a2, 97a3, 97a4, 97a5, and 97e for supplying a pneumatic pressure to the plurality of pressing chambers C1, C2, ..., C5, and Ce (C) formed between the base member 120 and the membrane 140 are formed in the base member 120. The pneumatic passages 97a1, 97a2, 97a3, 97a4, 97a5, and 97e may communicate with a pneumatic passage 98a connected to the base member 120 in the pneumatic passage 98 of the head body 110 to independently adjust the pneumatic pressure supplied to the pressing chambers C1, C2, ..., C5, Ce; C.

Flaps 1421, 1422, 1423, 1423, 1424, and 1425 (142) extending from the bottom plate 141 of the membrane 140 toward the base member 120 are fixed to the base member 120 via coupling members 129 that are coupled by bolts or pins. The membrane 140 is coupled to the base member 120, and thus the membrane 140 also rotates integrally by a rotational driving force transmitted from the rotation driving unit 105.

The membrane 140 is formed of a flexible material capable of bending and stretching by an external force, is coupled to at least one of the base member 120 and the head body 110, and thus forms the pressing chambers C1, C2, C3, C4, C5, and Ce (C), which are sealed, in a space between the membrane 140 and the base member 120. For example, the membrane 140 may be formed of polyurethane or a material similar thereto. A pressure of the pressing chamber C is adjusted by a pneumatic pressure supplied from the pressure adjusting unit AR. Accordingly, the pressure of the pressing chamber C may be adjusted, and thus a pressing force P for pressing the substrate G against the polishing pad 280 during the polishing process of the substrate G may be adjusted. Accordingly, a mechanical polishing rate of the substrate G is adjusted.

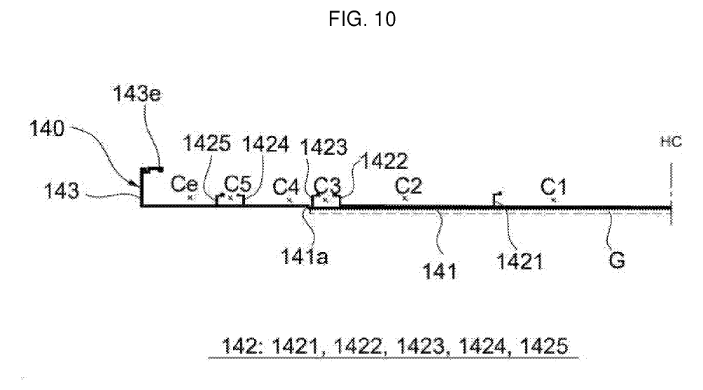

To this end, as illustrated in FIG. 10, the membrane 140 includes the bottom plate 141 that presses the substrate G, a side wall 143 extending upward from an edge of the bottom plate 141 and having an end portion 143e fixed to the base member 120, and a plurality of flaps 142 extending upward in concentric circular forms from an upper surface of the bottom plate 141 at predetermined distances from a rotation center HC of the polishing head 100. In the embodiment illustrated in the drawings, a configuration in which a side wall end portion 143e of the membrane 140 is fixedly installed on an upper surface of the base member 120 is provided as an example, but the present disclosure is not limited thereto, and a portion or the entirety of the side wall end portion 143e may be fixed to the edge ring 130.

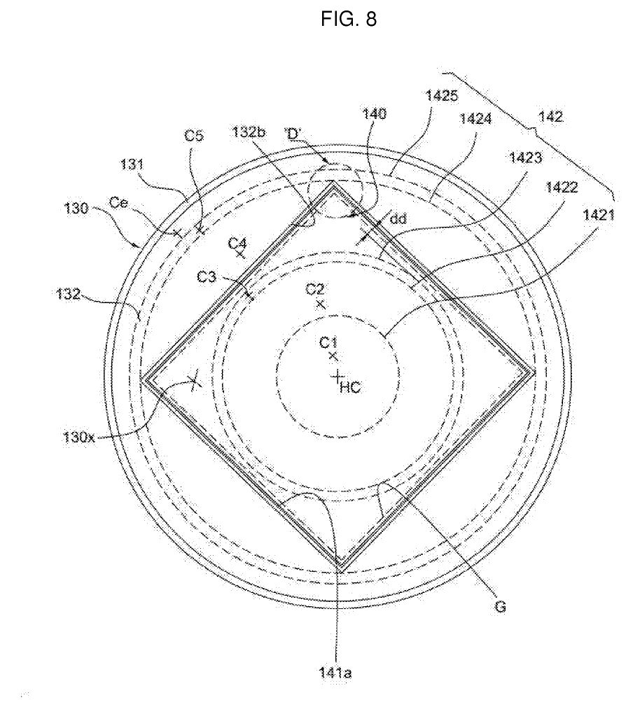

Here, the bottom plate 141 is formed in a circular shape, and as illustrated in FIG. 8, is formed to have a size sufficient to accommodate the polygonal substrate G. Assuming that the substrate G is formed in a square or a rectangular shape and has a length of one side of 500 mm, the bottom plate 141 is formed to have a diameter of 750 mm or more because an entire surface of the substrate G should be positioned below the bottom plate 141.

The edge ring 130 is coupled to the head body 110 of the body part and performs self-rotation 100r integrally with the head body 110 while a state in which the bottom surface of the edge ring 130 is in contact with the polishing pad 280 during the polishing process is maintained. Therefore, the substrate G is prevented from being separated to the outside of the edge ring 130 by a centrifugal force during the polishing process. An inward extension 132 positioned at a lower portion of the edge ring 130 is formed of a material (e.g., a resin such as PEEK or a plastic material) having a lower hardness than the polishing pad 280 and thus does not affect wear of the polishing pad 280 during the polishing process, thereby maintaining a constant polishing quality of the substrate G. The edge ring 130 may be entirely formed of the same material, but the inward extension 132 at the lower portion may be formed of a material having a lower hardness than the polishing pad 280, an upper portion of a circumferential portion 131 may be formed of a metallic material, and thus coupling stability with the head body may be secured.

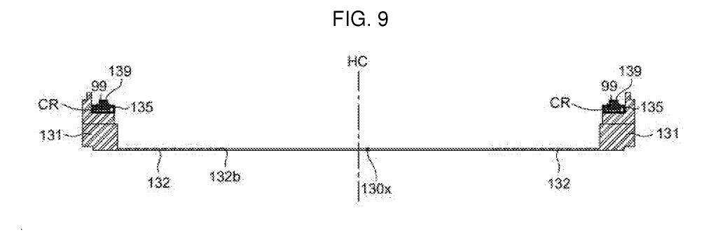

As illustrated in FIG. 9, the edge ring 130 includes the circumferential portion 131 that surrounds the bottom plate 141 of the membrane 140 in a circular ring shape and the inward extension 132 that protrudes and extends inward from a lower portion of the circumferential portion 131 toward the rotation center HC to form the receiving through portion 130x that accommodates the substrate G. Here, the inward extension 132 is positioned under the membrane bottom plate 141, and a position of the receiving through-portion 130x is determined such that the rotation center HC of the polishing head 100 is included in the receiving through-portion 130x.

As illustrated in FIG. 8, the receiving through-portion 130x corresponding to the shape and size of the substrate G is formed through the inward extension 132 extending inward from the circular circumferential portion 131 toward the rotation center HC. The receiving through-portion 130x is formed to have a greater size than the substrate G, and as illustrated in FIG. 3C, a size of the receiving through-portion 130x relative to the substrate G is determined according to a precision with which the polishing head 100 moves downward (indicated by reference numeral 100d1) to position the substrate G in the receiving through-portion 130x. For example, the receiving through-portion 130x may be greater than the substrate G by approximately 0.1% to 3%. Hereinafter, as illustrated in the drawings, a configuration in which the substrate G has a quadrangular shape and the receiving through-portion 130x has the same quadrangular shape as the substrate G will be mainly described.

Accordingly, the bottom plate 141 of the membrane 140 has a circular shape, but the membrane bottom plate 141 is exposed to a lower side only through the quadrangular receiving through-portion 130x, and a pressing force P is applied to the substrate G through the receiving through-portion 130x of the inward extension 132 in a state in which the substrate G is positioned in the receiving through-portion 130x.

At the same time, another portion of the membrane bottom plate 141 is placed on an upper surface of the inward extension 132 of the edge ring 130. Accordingly, among the pressing chambers C1, C2, ..., and Ce formed between the membrane 140 and the base member 120, a pressing chamber adjacent to an outer edge in a radial direction is in a state of pressing the inward extension 132 downward. Referring to FIG. 8, among the pressing chambers C, all the first chamber C1 formed by the first flap 1421, the second chamber C2 formed between the first flap 1421 and the second flap 1422, and the third chamber C3 formed between the second flap 1422 and the third flap 1423 are positioned inside the receiving through-portion 130x, and thus do not press the inward extension 132 downward. However, the fourth chamber C4 formed between the third flap 1423 and the fourth flap 1424 holds a boundary 132b of the receiving through-portion 130x, and thus a portion of the fourth chamber C4 presses the substrate G downward, and another portion of the fourth chamber C4 presses the inward extension 132 downward.

Accordingly, during the polishing process, the inward extension 132 presses the polishing pad 128 by the fourth chamber C4. When a pressing force applied to the polishing pad 128 by the inward extension 132 is large, the polishing pad 128 is deformed to be upwardly convex at a position immediately adjacent to a pressed position by the inward extension 132, and thus a polishing amount at an edge portion of the substrate G becomes non-uniform.

Thus, as illustrated in FIG. 9, the edge chamber CR for moving the edge ring 130 in an up-down direction is provided on an upper side of the circumferential portion 131 of the edge ring 130. The edge chamber CR is formed as a ring-shaped sealed space by a ring-shaped edge membrane 135 and a fixing member 139 that fixes the edge membrane 135 to the head body 110. A bottom surface of the edge membrane 135 is fixed to the edge ring 130, the fixing member 139 of the edge membrane 135 is coupled to the head body 110, and thus the edge ring 130 moves in an up-down direction 130d with respect to the head body 110 by a pressure of the edge chamber CR. Further, among the plurality of pneumatic passages 98 of the head body 110, a pneumatic passage 98b is connected to the edge chamber CR from the pressure adjusting unit AR, and thus a pressure of the edge chamber CR is independently and freely adjusted within a range of a positive pressure or a negative pressure. Accordingly, during the polishing process, the inward extension 132 of the edge ring 130 is pressed downward by pressures of the fourth chamber C4, the fifth chamber C5, and the outermost chamber Ce (this occurs in the same manner even when the pressures of the fifth chamber C5 and the outermost chamber Ce are negative pressures). During a portion or more of the polishing process, the edge chamber CR is adjusted to have a negative pressure value according to a pressing force for pressing the inward extension 132 downward, thereby offsetting a pressing force by which the inward extension 132 of the edge ring 130 presses the polishing pad 128 by the fourth chamber C4 and the like during the polishing process. As a result, the inward extension 132 is adjusted so as not to press the polishing pad 128, and thus excellent polishing quality may be obtained with a uniformly controlled polishing amount per unit time even at an edge of the substrate G accommodated in the receiving through-portion 130x.

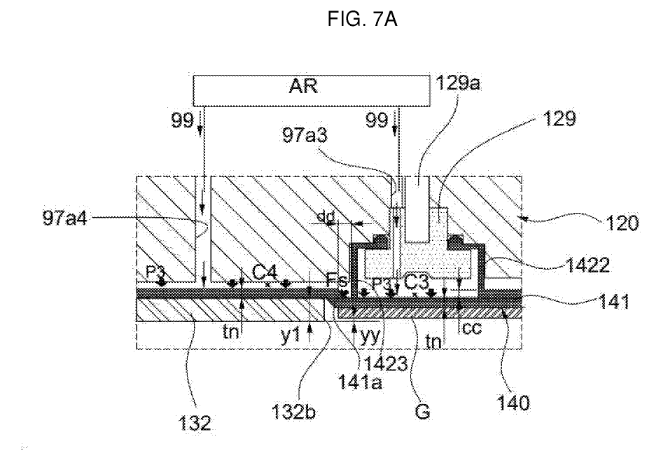

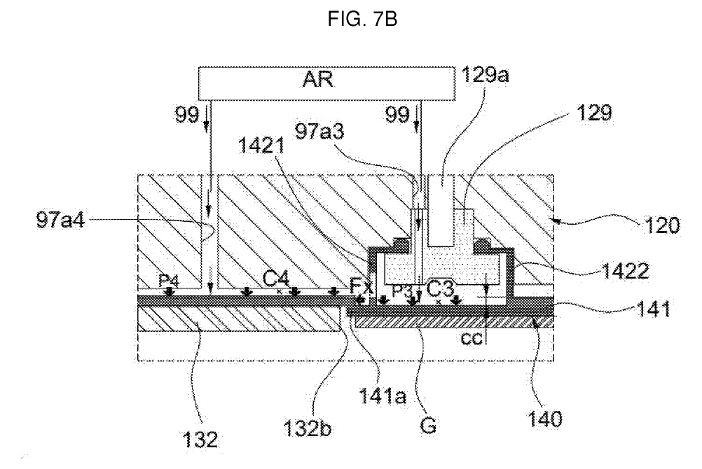

Here, the height of a bottom surface of the bottom plate 141 of the membrane 140 may be entirely formed to be constant, but according to an exemplary embodiment of the present disclosure, as illustrated in FIGS. 7A and 7B, in the receiving through-portion 130x of the edge ring 130, a bottom surface of the bottom plate 141 of the membrane 1340 is positioned lower than the bottom surface of the membrane bottom plate 141 positioned on the inward extension 132. Accordingly, the bottom plate protruding downward based on the end boundary 132b of the inward extension 132 may press the substrate G, and thus a close-contact state between the membrane bottom plate 141 and the substrate G may be further improved.

Here, as illustrated in FIGS. 7A and 7B, in order to form a height difference of the bottom surface of the bottom plate with respect to the end boundary 132b of the inward extension 132, a step 141a may be formed inside a portion of the membrane bottom plate 141 adjacent to the boundary 132b of the receiving through-portion 130x. Here, the wording “inside of a portion adjacent to the boundary 132b” includes substantially “a position in contact with the boundary 132b,” and at the same time, means "a position spaced 1/10,000 to 1/100 of a diameter of the bottom plate from the boundary 132b.” That is, this refers to a state in which the bottom surface of the bottom plate at a radially inner side with respect to the step 141a is close enough to be in contact with the entire surface of the substrate G.

Accordingly, the bottom surface of the membrane bottom plate 141 may be formed to have a stepwise height difference of the bottom surface of the bottom plate based on the step 141a, so that an upper surface of the substrate G and the bottom plate 141 are securely in close contact with each other near the end boundary 132b of the inward extension 132, and thus a pressing force may be accurately applied.

In this case, the step 141a formed on the bottom plate 141 may be inclined as illustrated in FIG. 7A, so that a height of a bottom surface at a radially inner side and a height of a bottom surface at a radially outer side of the step 141a are different from each other. Then, a force Fs is applied in a direction perpendicular to an inclined surface of the inclined step 141a by a pneumatic pressure in the fourth chamber C4, a horizontal component of the force Fs applied to an upper surface of the inclined step 141a is directed to a radially outward side, the bottom plate 141 at the edge portion of the substrate G is maintained in a completely unfolded state without being pushed, bent, or folded to the radially outer side, and thus a pressing force may be more accurately applied to the substrate G.

According to another embodiment of the present disclosure, the step 141a formed in the bottom plate 141 may be formed vertically as illustrated in FIG. 7B, and thus a height of a bottom surface at a radially inner side of the step 141a and a height of a bottom surface at a radially outer side thereof are different from each other. Then, a force Fx is applied radially outward in a direction parallel a vertical surface of the inclined step 141a due to the pneumatic pressure in the fourth chamber C4, the bottom plate 141 at the edge portion of the substrate G is maintained in a completely unfolded state radially outward, and thus a pressing force to the substrate G may be more accurately applied.

As illustrated in FIGS. 7A and 7B, the membrane bottom plate 141 is formed to have a uniform N^{th} thickness tn at a portion at which the step 141a is formed. In this case, as illustrated in the drawings, the thickness of the bottom plate in an edge area from the intermediate pressing chamber C3 to a radially outer edge of the bottom plate may be formed to the N^{th} thickness in which the step 141a is formed. In this case, among the second flap 1422 and the third flap 1423 forming the intermediate pressing chamber C3, the third flap 1423 closest to the step 141a is spaced apart from the step 141a by a minimum distance corresponding to 1/400 to 1/40 of the diameter of the bottom plate. That is, as illustrated in FIG. 8, the step 141a is formed in a polygonal shape, e.g., a quadrangular shape, at a radially inner side near the boundary 132b of the inward extension 132 according to the shape of the substrate G, the third flap 1423 closest to the step 141a in a radially inward direction is formed in a circular shape, and thus a distance dd is non-uniform. As the step 141a approaches a vertex of the substrate G, a distance from the third flap 1423 increases, and thus the step 141a and the third flap 1423 are spaced apart from each other by 1/400 to 1/40 of a diameter of the membrane bottom plate 141 based on the closest position.

Further, at a position spaced from the step 141a toward the rotation center HC, the second flap 1422 and the third flap 1423 arranged in two rows extend from the upper surface of the bottom plate 141 and are coupled to the base member 120, and thus an intermediate pressing chamber formed as the third chamber C3 in a space between the second flap 1422 and the third flap 1423 is made. In this case, the thickness of the bottom plate 141 in the intermediate pressing chamber is formed to be the same N^{th} thickness tn as the step 141a. Further, the bottom plate 141 from the intermediate pressing chamber to the rotation center HC is formed to have a thickness tn+cc that is thicker than the N^{th} thickness tn by a height indicated by "cc.” Here, the reference numeral "cc" may be determined as a height difference of the step 141a. Thus, in a central area of the bottom plate 141 from the intermediate pressing chamber C3 to the rotation center HC, a height of the upper surface of the bottom plate 141 may be formed to be the same as a height of the upper surface of the bottom plate 141 from the step 141a to the edge area.

Therefore, when the forces Fs and Fx are applied to the step 141a, the forces Fs and Fx are applied to the bottom plate having the N^{th} thickness that is smaller than a gap between the intermediate pressing chamber and the step 141a at a radially outer side compared to the bottom plate having the thick thickness tn+cc at a radially inner side of the intermediate pressing chamber, and thus the bottom plate may be further stretched. Therefore, in a state in which the membrane having a diameter of several thousand millimeters is not bent at or overlaps a position and the bottom plate 141 is fully and completely unfolded, the substrate G may be uniformly pressed at the edge area, and thus polishing quality of the substrate G may be improved.

As illustrated in FIG. 7A, in a state in which a positive pressure is not applied to the plurality of pressing chambers C1, C2, ..., Ce; C formed between the membrane 140 and the base member 120, in other words, in a state in which the bottom plate 141 is not convexly deformed downward by pressures P3, P4, ... (P) of the pressing chambers C, a thickness yy of the membrane bottom plate 141 and the inward extension 132 is determined such that, in a state in which the substrate G is accommodated in the receiving through-portion 130x and is in close contact with the bottom surface of the membrane bottom plate 141, the height of a bottom surface of the inward extension 132 of the edge ring 130 is positioned lower than that of a bottom surface of the substrate G by a height indicated by y2. Here, the height indicated by reference numeral y2 is determined to be smaller than a movement distance by which the membrane bottom plate 141 moves downward as the pressing chambers C1, C2, ... (C) are expanded while a positive pressure is applied to the pressing chambers C1, C2, ... (C). Therefore, as illustrated in FIG. 3B, in a process in which the polishing head 100 moves (indicated by 100d1) downward and seats the substrate G in the receiving through-portion 130x while aligned with the substrate G, the substrate G may be positioned to be surrounded by the edge ring 130. At the same time, when the polishing process starts to apply a positive pressure to the pressing chambers C1, C2,...; C, the membrane bottom plate 141 may be expanded downward, the bottom surface of the substrate G is in contact with the polishing pad 128, and thus a sufficient pressing force P is easily applied to the substrate G. Further, separation of the substrate G may be securely prevented by the edge ring 130 during the polishing process. Above all, even when there is a change in a thickness of the substrate G within a range indicated by reference numeral "y2," the polishing process may be performed while the substrate G is accommodated in the receiving through-portion 130x, and thus the substrate G having various thicknesses may be polished.

As illustrated in FIGS. 8 and 9, three or more flaps 142 including the first flap 1421, the second flap 1422, the third flap 1423, the fourth flap 1424, and the fifth flap 1425 are concentrically arranged on the bottom plate 141 of the membrane 140, extend upward, and are coupled to the base member 120 of the body part.

Accordingly, the first chamber C1 surrounded by the first flap 1421 with respect to the rotation center HC, the second chamber C2 formed between the first flap 1421 and the second flap 1422 in a ring shape, the third chamber C3 formed between the second flap 1422 and the third flap 1423 in a ring shape, the fourth chamber C4 formed between the third flap 1423 and the fourth flap 1424 in a ring shape, the fifth chamber C5 formed between the fourth flap 1424 and the fifth flap 1425 in a ring shape, and the outermost chamber Ce formed between the fifth flap 1425 and the side wall 143 in a ring shape are formed between the bottom plate 141 of the membrane 140 and the base member 120. Here, the third chamber C3, which is closest to the step 141a of the bottom plate 141 and serves as the intermediate pressing chamber, is formed to have a narrow width that is 1/200 to 1/10 of the diameter of the bottom plate 141, thereby assisting the membrane bottom plate 141 that presses the edge of the substrate G to be stretched by the forces Fs and Fx having the horizontal components.

Air supply ports connected to the pneumatic passages 97a1, 97a2, 97a3, 97a4, 97a5, and 97e are formed in these pressing chambers C1, C2, ..., and Ce (C) so that a pneumatic pressure is independently controlled. Here, volumes of the pressing chambers C1, ... that press the large-area substrate G are large, and thus according to an exemplary embodiment of the present disclosure, two or more air supply ports are arranged in each of the pressing chambers C1, C2, ..., air is simultaneously supplied or discharged through the two or more air supply ports, thereby reducing a time required to adjust a pressure of each pressure chamber C to a target pressure and improving control precision of a pressing force applied to the substrate. In particular, the air supply ports formed in the pressing chambers C1, C2,... are distributed symmetrically with respect to the rotation center HC. For example, the two air supply ports are arranged at 180-degree intervals, the three air supply ports are arranged at 120-degree intervals, or the four air supply ports are arranged at 90-degree intervals. Therefore, in a process of controlling a pressure of one pressing chamber through the plurality of air supply ports, local pressure deviation within the pressure chamber is prevented from occurring.

As illustrated in FIG. 8, it is preferable that the two or more chambers are arranged inside the receiving through-portion 130x. Therefore, a pressing force applied to a central portion of the substrate is adjusted by the first chamber C1 and the second chamber C2, and the third chamber C3 adjacent to the step 141a and having a narrow width serves as the intermediate pressing chamber to assist in maintaining a completely unfolded state without folding or bending while being stretched by the radially outward forces Fs and Fx applied to the step 141a. As described above, the thickness tn+cc of the bottom plate of the first chamber C1 and the second chamber C2 is greater than the thickness tn of the third chamber C3 and the fourth chamber C4, and thus the membrane bottom plate 141 that presses the edge of the substrate G is maintained in a completely unfolded state by applying the forces Fs and Fx having horizontal components in a radially outward direction. Here, the third flap 1443 of the third chamber C3 is spaced a predetermined distance dd from the step 141a, but it is preferable that this separation distance dd is as small as possible. According to an exemplary embodiment of the present disclosure, the third flap 1433 is disposed to be substantially in contact with the step 141a with only a gap of 0.1 mm to 10 mm. Further, the step 141a is also disposed to be substantially in contact with the boundary 143b of the inward extension 132, and thus the third flap 1433 is disposed to be substantially inscribed in the receiving through-portion 130x, which corresponds to the boundary 143b of the inward extension 132.

Further, the fourth flap 1434 forming a radially outer boundary of the fourth chamber C4 is disposed to be circumscribed about vertices of the polygonal receiving through-portion 130x. Accordingly, the fourth chamber C4 presses a vicinity of the vertex of the substrate G, and at the same time, downwardly presses a portion of the inward extension 132 of the edge ring 130. Thus, the fourth chamber C4 may be formed by the third flap 1433 inscribed in the receiving through-portion 130x and the fourth flap 1434 circumscribed about a vertex of the receiving through-portion 130x, and thus the amount of polishing of the substrate G in the vicinity of the vertex may be precisely adjusted by precisely pressing the vicinity of the vertex of the polygonal substrate G.

An absolute value of a negative pressure of the edge chamber CR is controlled to be changed in proportion to the pressing force P4 applied to the substrate G by the fourth chamber C4. Accordingly, a polishing deviation may be prevented from occurring along the edge of the substrate due to a rebound effect of the polishing pad by pressing the polishing pad 280 by the inward extension 132 of the edge ring 130. Thus, polishing quality at the edge of the substrate may be improved.

As described above, according to the present disclosure, a polishing process can be performed in a state in which an entire surface of a large-area substrate having a quadrangular flat plate shape having a length of one side of 500 mm or more is in contact with a polishing pad, and thus a deviation in a polishing amount according to a position of the substrate can be minimized, and polishing quality can be improved.

Further, according to the present disclosure, a polishing process can be performed while a substrate is pressed against a polishing pad in a state in which the substrate is accommodated in a receiving through-portion formed to correspond to a shape of the substrate during the polishing process of the polygonal substrate, and thus, even when the substrate has a non-circular shape, distortion and jamming of the substrate during the polishing process can be prevented, and a central portion, an edge area, and a vertex area of the substrate can be uniformly polished.

Further, according to the present disclosure, a receiving through-portion of an edge ring is formed to correspond to a shape of a non-circular substrate, a step is formed at or immediately inside a boundary of the receiving through-portion, a bottom surface of a bottom plate of a membrane in the receiving through-portion is disposed to be more convex downward than a bottom surface of a bottom plate in a radially outer area, and thus a pressing force can be smoothly applied to the large-area substrate.

Above all, according to the present disclosure, a thickness of a bottom plate of a membrane having a step is uniformly formed with an N^{th} thickness, a force that radially outwardly pushes the bottom plate of the membrane near the step is introduced by a pressing force in a pressing chamber including the step, and thus the bottom plate of the membrane in an area pressing an edge of the substrate can be changed into a completely stretched state, and an accurate pressing force can be applied to the edge of the large-size substrate.

Further, according to the present disclosure, a thickness of a bottom plate of a membrane at a portion at which a step is formed and in a radially outer area of the step can be smaller than a thickness of the bottom plate from a position spaced radially inward from the position at which the step is formed by an intermediate pressing chamber to a rotation center, the bottom plate of the membrane can be easily stretched by a force for radially outwardly pushing the intermediate pressing chamber and the step, a pressing force can be accurately applied to an edge portion of the substrate through the flatly stretched bottom plate of the membrane, and thus polishing quality can be improved.

As described above, exemplary embodiments of the present disclosure have been described, but those skilled in the art may understand that the present disclosure may be variously modified and changed without departing from the spirit and scope of the present disclosure described in the appended claims.

What is claimed is:

1. A polishing head for a polishing apparatus, which presses a substrate having a non-circular shape during a polishing process, the polishing head comprising:
a body part configured to receive a rotational driving force and formed to be rotatable;
a membrane coupled to the body part, configured to form a pressing chamber between the body part and the membrane, and having a bottom surface that presses the substrate; and
an edge ring having a receiving through-portion accommodating the substrate in the non-circular shape and coupled to the body part,
wherein the substrate is accommodated in the receiving through-portion during the polishing process.

2. The polishing head of claim 1, wherein the edge ring has an inward protrusion extending from a circumference portion of the edge ring to below the bottom surface of the membrane, and the receiving through-portion is provided in the inward protrusion.

3. The polishing head of claim 2, wherein a bottom plate of the membrane has a different shape from the receiving through-portion.

4. The polishing head of claim 2, wherein a bottom plate of the membrane has a circular shape, and the receiving through-portion has a polygonal shape.

5. The polishing head of claim 4, wherein the bottom plate has a bottom surface protruding further toward the substrate in the receiving through-portion.

6. The polishing head of claim 5, wherein the bottom plate has a step formed inside the receiving through-portion, and the step is inclined such that a height of a bottom surface at a radially inner side of the step and a height of a bottom surface at a radially outer side of the step are different from each other.

7. The polishing head of claim 6, wherein, the bottom plate at a portion at which the step is formed is formed to have a constant N^{th} thickness, and at a position spaced apart from the step toward a rotation center, a second flap and a third flap arranged in two columns extend from the bottom plate and are coupled to the body part, an intermediate pressing chamber is formed in a space between the second flap and the third flap, and a thickness of the bottom plate in the intermediate pressing chamber is formed to be the N^{th} thickness.

8. The polishing head of claim 7, wherein a thickness of a bottom plate in a central area from the intermediate pressing chamber to the rotation center is greater than the N^{th} thickness.

9. The polishing head of claim 7, wherein a thickness of a bottom plate in an edge area from the intermediate pressing chamber to an edge is formed to be an N^{th} thickness.

10. The polishing head of claim 8, wherein a height of an upper surface of the bottom plate in the central area is the same as a height of an upper surface of a bottom plate from the step to an outer area.

11. The polishing head of claim 5, wherein, based on a state in which the bottom plate is not convexly downward by a pressure of the pressing chamber, a bottom surface of the substrate in close contact with the bottom plate of the membrane is disposed closer to the membrane than the bottom surface of the inward protrusion.

12. The polishing head of claim 7, wherein a third flap extends at a position spaced a predetermined distance from the step toward a rotation center and is coupled to the body part.

13. The polishing head of claim 12, wherein a flap is formed in two or more columns including a second flap and the third flap, and an intermediate pressing chamber is formed between the second flap and the third flap, and the second flap and the third flap are arranged concentrically.

14. The polishing head of claim 13, wherein the step is formed in the shape of the receiving through-portion.

15. The polishing head of claim 14, wherein the third flap has a circular shape spaced apart from the step by a minimum length that is 1/400 to 1/40 of a diameter of the bottom plate of the membrane.

16. The polishing head of claim 13, wherein three or more flaps extend from the bottom plate and are coupled to the body part.

17. The polishing head of claim 16, wherein the flat includes:
the second flap disposed inside the receiving through-portion; and
a fourth flap disposed at a position circumscribed about a vertex of the receiving through-portion,
and wherein the second flap and the fourth flap are arranged concentrically.

18. The polishing head of claim 17, wherein the pressing chamber is formed as a plurality of pressing chambers partitioned by the second flap, the third flap, and the fourth flap, and pressures of the plurality of pressing chambers are independently controlled.

19. The polishing head of claim 17, wherein one or more of the plurality of pressing chambers partitioned by the second flap, the third flap, and the fourth flap have air supply ports configured to receive a pneumatic pressure at two or more positions and receive the pneumatic pressure simultaneously at the two or more positions.

20. The polishing head of claim 19, wherein the air supply ports are distributed symmetrically based on the rotation center.
